(19) United States
(12) Patent Application Publication
(10) Pub. No.: US 2026/0136659 A1
(43) Pub. Date: May 14, 2026

(54) SEMICONDUCTOR DEVICE AND METHOD FOR FABRICATING THE SAME

(71) Applicant: Samsung Electronics Co., Ltd., Suwon-si (KR)

(72) Inventors: Ji-Myoung Lee, Suwon-si (KR); Seung Kyu Kim, Suwon-si (KR); Kwang-Young Lee, Suwon-si (KR); Se Ki Hong, Suwon-si (KR)

(21) Appl. No.: 19/220,307

(22) Filed: May 28, 2025

(30) Foreign Application Priority Data
Nov. 14, 2024 (KR) 10-2024-0162099

(51) Int. Cl. H10D 84/85; H10D 84/01

(52) U.S. Cl. CPC H10D 84/856; H10D 84/0186; H10D 84/851

(57) ABSTRACT

A semiconductor device including a first region and a second region arranged in a first direction. The semiconductor device may include a first active pattern extending in a second direction intersecting the first direction in the first region, a second active pattern extending in the second direction in the second region, a gate structure extending in a third direction intersecting the first and second directions on the first and second active patterns and a via structure extending in the first direction across the first and second regions, on a side surface of the gate structure. The via structure may include a first via pattern and a second via pattern stacked in the first direction, and a first liner insulating film extending along a side surface of the second via pattern, on the upper surface of the first via pattern. A boundary may exist between the first and second via patterns.

### CROSS-REFERENCE TO PRIORITY APPLICATION

This application claims priority under 35 U.S.C. § 119 to Korean Patent Application No. 10-2024-0162099, filed on Nov. 14, 2024, the disclosure of which is hereby incorporated by reference in its entirety herein.

### BACKGROUND

### 1. Technical Field

The present disclosure relates to semiconductor devices and methods for fabricating the same, such as, but not necessarily limited to, semiconductor devices including a stacked multi-gate transistor and methods for the fabrication thereof.

### 2. Description of the Related Art

As one of the scaling technologies for increasing the density of integrated circuit devices, multi-gate transistors have been proposed, in which a fin-shaped or nanowire-shaped silicon body is formed on a substrate, and a gate is formed on the surface of the silicon body.

Since these multi-gate transistors utilize three-dimensional (3D) channels, scaling is facilitated. In addition, the current control capability can be improved without increasing the gate length of the multi-gate transistors. Furthermore, the short channel effect (SCE), in which the potential of channel regions is affected by drain voltages, can be effectively suppressed.

### SUMMARY

One aspect of present disclosure relates to a semiconductor device with improved integration and performance.

One aspect of the present disclosure relates to a method for fabricating a semiconductor device with improved integration and performance.

Aspects of the present disclosure, however, are not restricted to those set forth herein. The above and other aspects of the present disclosure will become more apparent to one of ordinary skill in the art to which the present disclosure pertains by referencing the detailed description of the present disclosure given below. According to an aspect of the present disclosure, there is provided a semiconductor device including a first region and a second region sequentially arranged in a first direction, the semiconductor device comprising, a first active pattern extending in a second direction intersecting the first direction in the first region, a second active pattern extending in the second direction in the second region, a gate structure extending in a third direction intersecting the first and second directions on the first and second active patterns and a via structure extending in the first direction across the first and second regions, on a side surface of the gate structure, wherein the via structure includes a first via pattern and a second via pattern sequentially stacked in the first direction, and a first liner insulating film extending along a side surface of the second via pattern, on the upper surface of the first via pattern, and a boundary exists between the first and second via patterns.

One aspect of the present disclosure relates to a semiconductor device. The semiconductor device may a first active pattern and a second active pattern spaced apart from each other in a first direction and extending in a second direction intersecting the first direction. The semiconductor device may further include a gate structure extending in a third direction intersecting the first and second directions, and penetrated by each of the first and second active patterns. The semiconductor device may still further include a first source/drain pattern connected with the first active pattern, on a side surface of the gate structure, and a second source/drain pattern connected with the second active pattern, on the side surface of the gate structure. The semiconductor device may yet further include an interlayer insulating film covering the first and second source/drain patterns, on the side surface of the gate structure. The semiconductor device may additionally include a via hole extending in the first direction within the interlayer insulating film and spaced apart from the first and second source/drain patterns in the third direction. The semiconductor device may still additionally include a via structure filling at least a portion of the via hole, wherein the via hole includes a first sub-hole and a second sub-hole on or above the first sub-hole, with a width of the second sub-hole may be greater than or equal to a width of the first sub-hole. The via structure may include a first via pattern filling at least a portion of the first sub-hole, a first liner insulating film extending along a side surface of the second sub-hole, and a second via pattern connected with the first via pattern, on the first liner insulating film. At a boundary or interface between the first and second via patterns, a width of the first via pattern may be greater than a width of the second via pattern.

Another aspect of the present disclosure relates toa semiconductor device. The semiconductor device may include a substrate including a first surface and a second surface opposite to each other in a first direction. The semiconductor device may further include a first active pattern extending in a second direction intersecting the first direction on the first surface, a second active pattern spaced farther from the first surface than the first active pattern in the first direction, and extending in the second direction, a gate structure extending in a third direction intersecting the first and second directions, and penetrated by each of the first and second active patterns. The semiconductor device may still further include a first source/drain pattern connected with the first active pattern, on a side surface of the gate structure, and a second source/drain pattern connected with the second active pattern, on the side surface of the gate structure. The semiconductor device may yet further include backside wiring patterns on the second surface and a via structure extending in the first direction to electrically connect the second source/drain pattern and the backside wiring patterns. The via structure may include a first via pattern and a second via pattern sequentially stacked on the backside wiring patterns, and a liner insulating film extending along a side surface of the second via pattern, on an upper surface of the first via pattern, with a boundary between the first and second via patterns.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent with reference to the drawings and detail description below.

FIG. 1 is an exemplary circuit diagram of a semiconductor device according to some embodiments of the present disclosure.

FIG. 2 is an example layout diagram of the semiconductor device according to some embodiments of the present disclosure.

FIG. 3 is a cross-sectional view taken along line A-A of FIG. 2.

FIG. 4 is a cross-sectional view taken along line B-B of FIG. 2.

FIG. 5 is a cross-sectional view taken along line C-C of FIG. 2.

FIG. 6 is a cross-sectional view taken along line D-D of FIG. 2.

FIGS. 7A through 7E are various enlarged views for region R1 of FIG. 5.

FIG. 8 is a cross-sectional view of a semiconductor device according to some embodiments of the present disclosure.

FIGS. 9A through 9C are various enlarged views for explaining region R2 of FIG. 8.

FIGS. 10 through 24 are diagrams illustrating a method for manufacturing a semiconductor device according to some embodiments of the present disclosure.

### DETAILED DESCRIPTION

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that spatially relative terms such as “above,” “upper,” “upper portion,” “upper surface,” “below,” “lower,” “lower portion,” “lower surface,” “side surface,” and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

Components or layers described with reference to being “sequential” or “sequentially stacked” in a particular direction or manner may be at layered, adjoined, proximate, orientated, or otherwise arranged with respect to each other to achieve the illustrated or contemplated relativity, optionally with other components, layers, etc. therebetween. Components or layers described with reference to “overlap” in a particular direction may be at least partially obstructed by one another when viewed along a line extending in the particular direction or in a plane perpendicular to the particular direction. The term “surrounding” or “covering” or “filling” as may be used herein may not require completely surrounding or covering or filling the described elements or layers, but may, for example, refer to partially surrounding or covering or filling the described elements or layers, for example, with voids, spaces, or other discontinuities throughout. The term “penetrate” may be used to express extending into but not necessarily requiring extending completely through. The term “exposed” may be used to describe relationships between elements and/or certain intermediate processes in fabricating a completed semiconductor device, but may not necessarily require exposure of the particular region, layer, structure or other element in the context of the completed device.

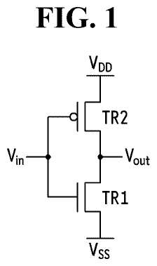

A semiconductor device according to example embodiments will hereinafter be described with reference to FIGS. 1 through 9C. The embodiments disclosed with respect to FIGS. 1 through 9C describe a semiconductor device as an inverter, but this is presented merely for exemplary purposes. Those skilled in the art to which the present disclosure pertains will understand that the technical spirit of the present disclosure can also be applied to various other logic devices, such as AND gates, NAND gates, OR gates, NOR gates, and XOR gates, or various other semiconductor devices, such as static random access memory (SRAM) devices.

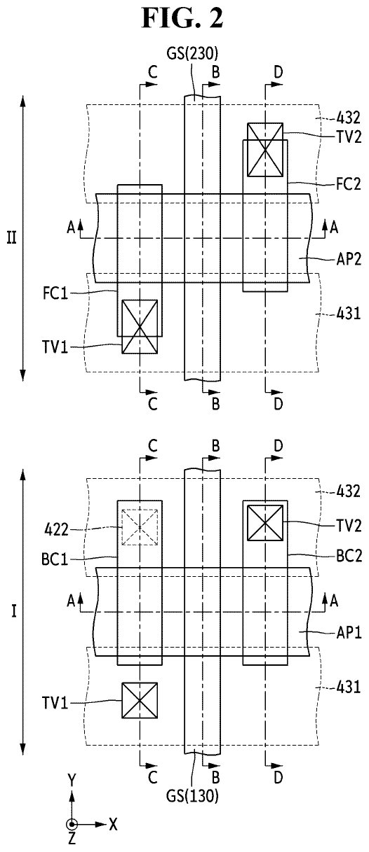

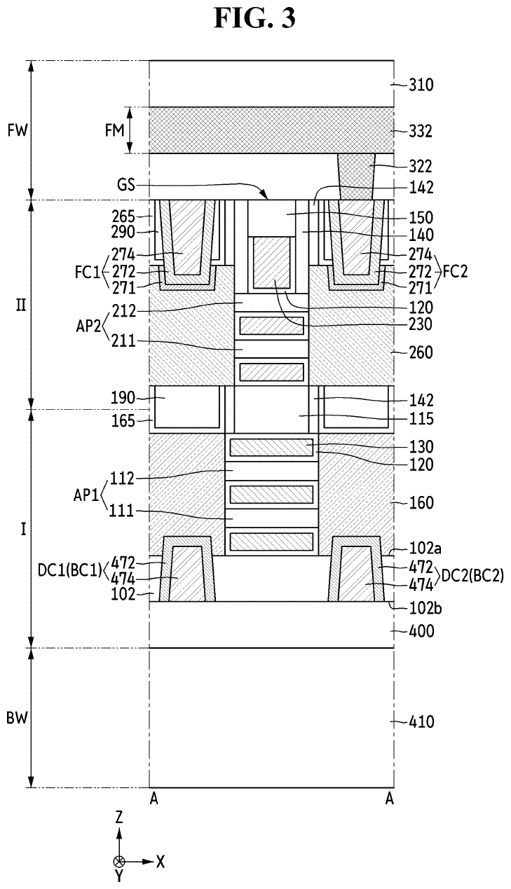

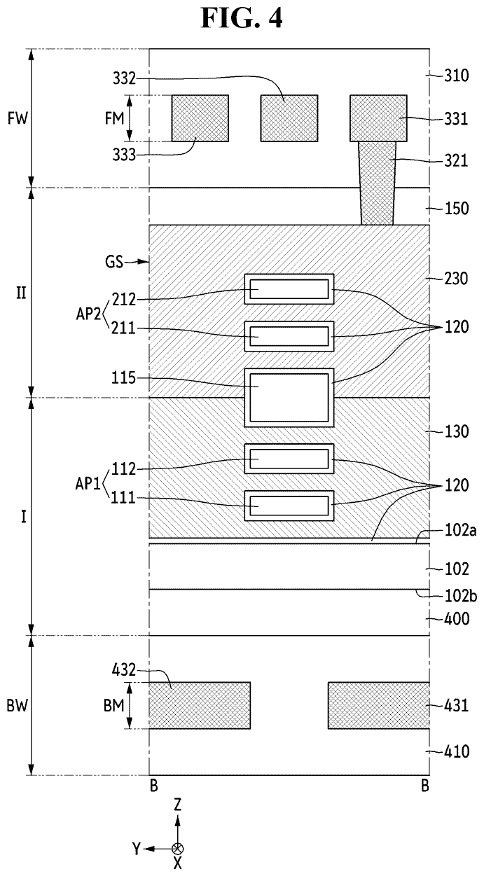

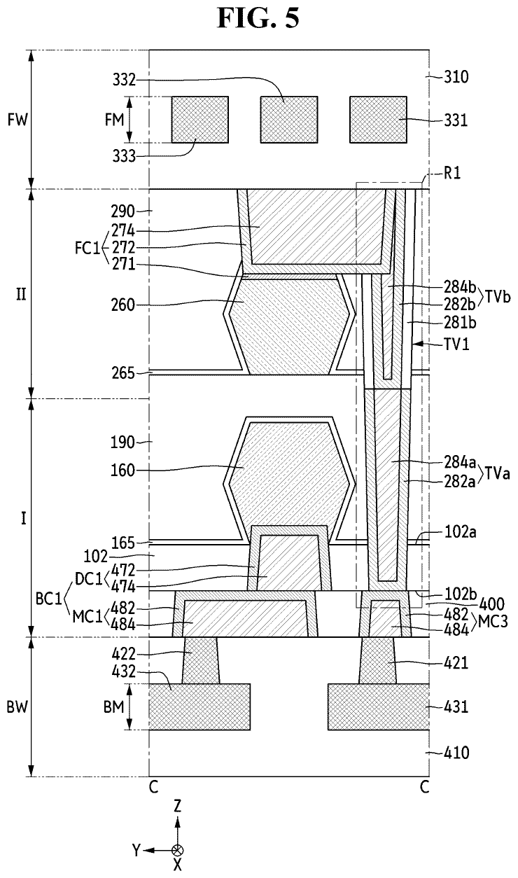

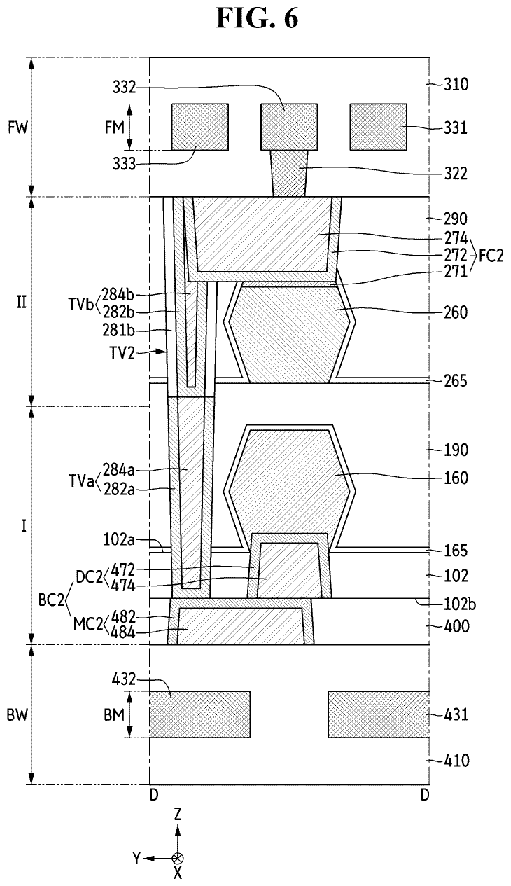

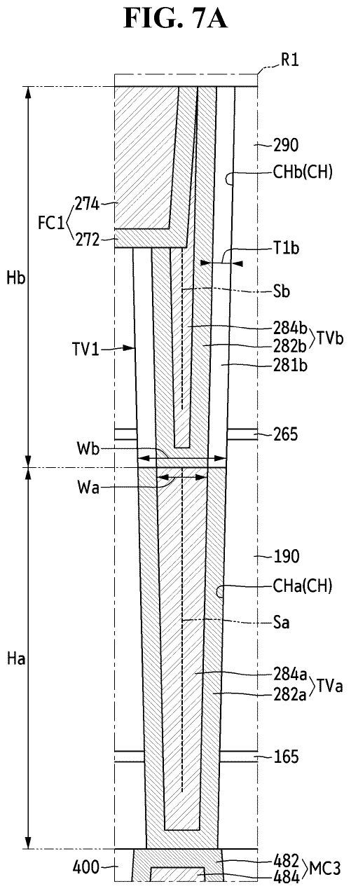

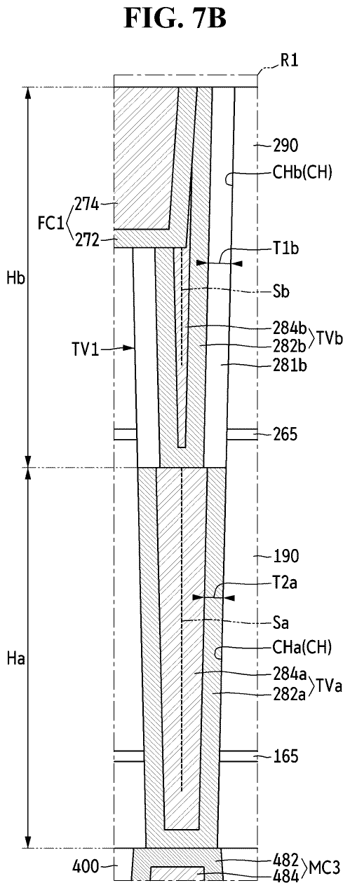

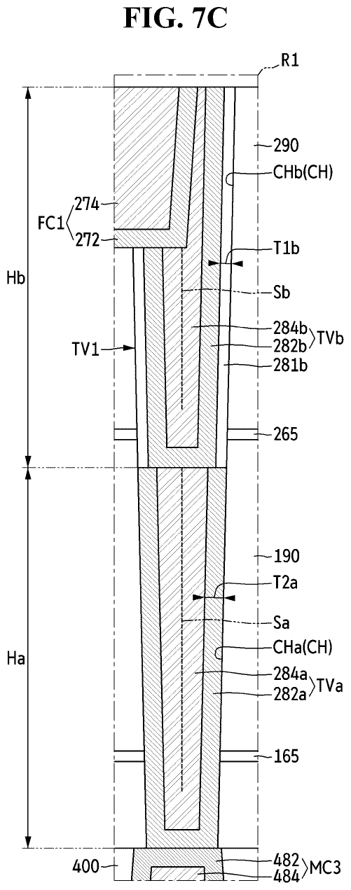

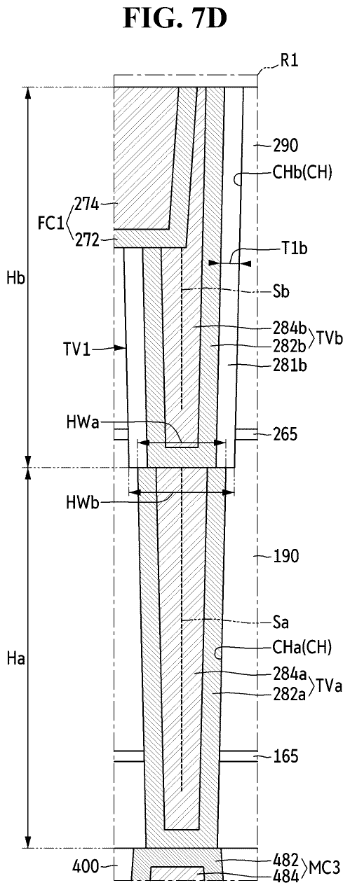

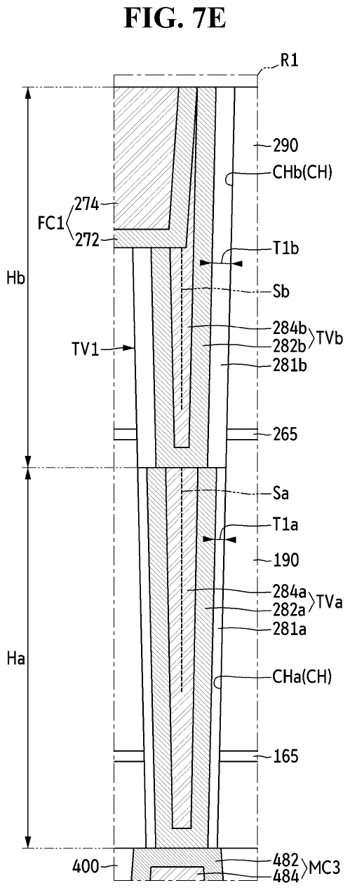

FIG. 1 is an example circuit diagram for explaining a semiconductor device according to some embodiments of the present disclosure. FIG. 2 is an example layout diagram for explaining the semiconductor device according to some embodiments. FIG. 3 is a cross-sectional view taken along line A-A of FIG. 2. FIG. 4 is a cross-sectional view taken along line B-B of FIG. 2. FIG. 5 is a cross-sectional view taken along line C-C of FIG. 2. FIG. 6 is a cross-sectional view taken along line D-D of FIG. 2. FIGS. 7A through 7E are various enlarged views for explaining region R1 of FIG. 5.

Referring to FIG. 1, the semiconductor device according to some embodiments may be provided as an inverter.

For example, the semiconductor device according to some embodiments may include a first transistor TR1 and a second transistor TR2, which are connected in series between a first power node V_{SS} and a second power node V_{DD}. The first transistor TR1 may be an n-type field-effect transistor (NFET), and the second transistor TR2 may be a p-type field-effect transistor (PFET). The source of the first transistor TR1 may be connected with the first power node V_{SS}, and the source of the second transistor TR2 may be connected with the second power node V_{DD}. An input signal Vᵢₙ of the inverter may be applied to the gates of the first and second transistors TR1 and TR2. An output signal Vₒᵤₜ of the inverter may be output from a node where the drain of the first transistor TR1 and the drain of the second transistor TR2 are connected.

Referring to FIGS. 1 through 7A, the semiconductor device according to some embodiments includes a first region I and a second region II.

The first and second regions I and II may be sequentially stacked in a first direction Z. In the following description, the second transistor TR2 is provided in the first region I, and the first transistor TR1 is provided in the second region II. However, this is merely presented for exemplary purposes, and those skilled in the art will understand that the first transistor TR1 may be provided in the first region I and the second transistor TR2 in the second region II.

Additionally, the semiconductor device according to some embodiments includes a substrate 102, a first active pattern AP1, a second active pattern AP2, an intermediate insulating pattern 115, a gate structure GS, a first source/drain pattern 160, a first etch stop film 165, a first interlayer insulating film 190, a second source/drain pattern 260, a second etch stop film 265, a second interlayer insulating film 290, a first via structure TV1, a second via structure TV2, a first frontside source/drain contact FC1, a second frontside source/drain contact FC2, a frontside wiring structure FW, a first backside source/drain contact BC1, a second backside source/drain contact BC2, and a backside wiring structure BW.

The substrate 102 may be bulk silicon or silicon-on-insulator (SOI). Alternatively, the substrate 102 may be a silicon substrate or may include materials, for example, silicon-germanium (SiGe), SiGe-on-insulator (SGOI), indium antimonide, a lead telluride compound, indium arsenide, indium phosphide, gallium arsenide, or gallium antimonide. Alternatively, the substrate 102 may be an epitaxial layer formed on a base substrate.

In some embodiments, the substrate 102 may be an insulating substrate that includes an insulating material. For example, the substrate 102 may include at least one of silicon oxide, silicon oxynitride, silicon oxycarbon nitride, or a combination thereof, but is not limited thereto. For example, the substrate 102 may include a silicon oxide film.

The substrate 102 may include a first surface 102a and a second surface 102b that are opposite to each other in the first direction Z. In this specification, the first surface 102a may also be referred to as the front side of the substrate 102, and the second surface 102b may also be referred to as the back side of the substrate 102.

The first active pattern AP1 may be disposed in the first region I. The first active pattern AP1 may be disposed on the first surface 102a of the substrate 102. The first active pattern AP1 may be spaced apart from the substrate 102 in the first direction Z. The first active pattern AP1 may extend longitudinally in a second direction X intersecting the first direction Z.

In some embodiments, the first active pattern AP1 may include a plurality of lower bridge patterns 111 and 112, which are sequentially stacked in the first direction Z and spaced apart from each other. The lower bridge patterns 111 and 112 may be used as a channel region of a multi-bridge channel field effect transistor (MBCFET®) including a multi-bridge channel in the first region I. The number of bridge patterns included in the first active pattern AP1 is presented merely for exemplary purposes and is not limited to that illustrated.

The second active pattern AP2 may be disposed in the second region II. The second active pattern AP2 may be spaced apart from the first active pattern AP1 in the first direction Z. Relative to the first surface 102a of the substrate 102, the second active pattern AP2 may be spaced farther than the first active pattern AP1. The second active pattern AP2 may extend longitudinally in the second direction X.

In some embodiments, the second active pattern AP2 may include a plurality of upper bridge patterns 211 and 212, which are sequentially stacked in the first direction Z and spaced apart from each other. The upper bridge patterns 211 and 212 may be used as the channel region of an MBCFET® including a multi-bridge channel in the second region II. The number of bridge patterns included in the second active pattern AP2 is presented merely for exemplary purposes and is not limited to that illustrated.

The first and second active patterns AP1 and AP2 may each include an elemental semiconductor material such as silicon (Si) or germanium (Ge). Alternatively, the first and second active patterns AP1 and AP2 may each include a compound semiconductor, for example, a group IV-IV compound semiconductor or a group III-V compound semiconductor. The group IV-IV compound semiconductor may include, for example, a binary or a ternary compound including at least two of carbon (C), Si, Ge, or tin (Sn), or a compound obtained by doping the binary or ternary compound with a group IV element. The group III-V compound semiconductor may include, for example, a binary, ternary, or quaternary compound obtained by combining at least one group III element such as aluminum (Al), gallium (Ga), or indium (In), with at least one group V element such as phosphorus (P), arsenic (As), or antimony (Sb).

The intermediate insulating pattern 115 may be positioned between the first and second active patterns AP1 and AP2 in the first direction Z. For example, the intermediate insulating pattern 115 may be spaced apart from the first active pattern AP1 in the first direction Z, and the second active pattern AP2 may be spaced apart from the intermediate insulating pattern 115 in the first direction Z. In some embodiments, the intermediate insulating pattern 115 may extend longitudinally in the second direction X.

The intermediate insulating pattern 115 may include, for example, at least one of silicon oxide, silicon oxynitride, silicon oxycarbon nitride, or a combination thereof, but is not limited thereto. For example, the intermediate insulating pattern 115 may include a silicon nitride film.

The gate structure GS may be formed on the first and second active patterns AP1 and AP2. The gate structure GS may intersect the first and second active patterns AP1 and AP2. For example, the gate structure GS may extend in a third direction Y intersecting the first direction Z and the second direction X.

In some embodiments, the gate structure GS may include a gate dielectric film 120, a first gate electrode 130, a second gate electrode 230, a first gate spacer 140, a second gate spacer 142, and a gate capping film 150.

The gate dielectric film 120 may be positioned between the first active pattern AP1 and the first gate electrode 130, and between the second active pattern AP2 and the second gate electrode 230. The gate dielectric film 120 may include a dielectric material, for example, at least one of silicon oxide, silicon oxynitride, silicon nitride, a high-k dielectric material with a greater dielectric constant than silicon oxide, or a combination thereof. The high-k dielectric material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or a combination thereof, but is not limited thereto.

The gate dielectric film 120 is illustrated as a single layer, but this is presented merely for exemplary purposes. Alternatively, the gate dielectric film 120 may be a multilayer film formed by stacking a plurality of dielectric films. For example, the gate dielectric film 120 may include an interface film and a high-k film sequentially stacked on the first and second active patterns AP1 and AP2. The interface film may include, for example, an oxide film formed by oxidizing the surfaces of the first and second active patterns AP1 and AP2. The high-k film may include, for example, the high-k dielectric material having a greater dielectric constant than silicon oxide.

In some embodiments, a portion of the gate dielectric film 120 may be positioned between the substrate 102 and the first gate electrode 130. For example, the gate dielectric film 120 may further extend along the first surface 102a of the substrate 102. In some embodiments, a portion of the gate dielectric film 120 may be positioned between the intermediate insulating pattern 115 and the first gate electrode 130, and/or between the intermediate insulating pattern 115 and the second gate electrode 230. For example, the gate dielectric film 120 may further extend along the periphery of the intermediate insulating pattern 115.

The first gate electrode 130 may be disposed in the first region I. The first gate electrode 130 may intersect the first active pattern AP1. For example, each of the lower bridge patterns 111 and 112 may extend in the second direction X and penetrate the first gate electrode 130. The first gate electrode 130 may surround the peripheries of the lower bridge patterns 111 and 112.

The second gate electrode 230 may be disposed in the second region II. The second gate electrode 230 may intersect the second active pattern AP2. For example, each of the upper bridge patterns 211 and 212 may extend in the second direction X and penetrate the second gate electrode 230. The second gate electrode 230 may surround the peripheries of the upper bridge patterns 211 and 212.

The first and second gate electrodes 130 and 230 may each include a conductive material, for example, at least one of TiN, WN, TaN, Ru, TiC, TaC, Ti, Ag, Al, TiAl, TiAlN, TiAlC, TaCN, TaSiN, Mn, Zr, W, or a combination thereof, but are not limited thereto. The first and second gate electrodes 130 and 230 may each be formed by a replacement process, but are not limited thereto.

The first and second gate electrodes 130 and 230 are illustrated as single layers, but this is presented merely for exemplary purposes. Alternatively, the first and second gate electrodes 130 and 230 may be formed as multilayer conductive films. For example, the first and second gate electrodes 130 and 230 may each include a work function control film and a filling electrode film filling a space formed by the work function control film. The work function control film may include, for example, at least one of TiN, TaN, TiC, TaC, TiAlC, or a combination thereof. The filling electrode film may include, for example, W or Al.

In some embodiments, the first and second gate electrodes 130 and 230 may include different conductive materials. For example, the first and second gate electrodes 130 and 230 may include work function control films of different conductivity types. For example, the first gate electrode 130 may include a p-type work function control film, and the second gate electrode 230 may include an n-type work function control film.

In FIG. 4, the first and second gate electrodes 130 and 230 are illustrated as being in direct contact with each other, but this is presented merely for exemplary purposes. If necessary, the first and second gate electrodes 130 and 230 may be electrically separated. For example, the intermediate insulating pattern 115 may extend in the third direction Y to separate the first gate electrode 130 from the second gate electrode 230.

The first gate spacer 140 may extend along the side surfaces of the first and second gate electrodes 130 and 230. The first and second active patterns AP1 and AP2 may each extend in the second direction X to penetrate the first gate spacer 140. The first gate spacer 140 may include an insulating material, for example, at least one of silicon oxide, silicon nitride, silicon oxynitride, silicon oxycarbide, silicon boron nitride, silicon carbon boron nitride, silicon oxycarbonitride, or a combination thereof, but is not limited thereto.

In some embodiments, a portion of the gate dielectric film 120 may be positioned between the second gate electrode 230 and the first gate spacer 140. For example, the gate dielectric film 120 may further extend along the inner side surface of the first gate spacer 140.

The second gate spacer 142 may extend along the outer side surface of the first gate spacer 140. The second gate spacer 142 may include an insulating material, for example, at least one of silicon oxide, silicon nitride, silicon oxynitride, silicon oxycarbide, silicon boron nitride, silicon carbon boron nitride, silicon oxycarbonitride, or a combination thereof, but is not limited thereto.

In some embodiments, a portion of the second gate spacer 142 may further extend along the side surface of the intermediate insulating pattern 115.

The first source/drain pattern 160 may be formed on both sides of the gate structure GS. The first source/drain pattern 160 may be connected with the first active pattern AP1. For example, each of the lower bridge patterns 111 and 112 may penetrate the first gate electrode 130, the first gate spacer 140, and the second gate spacer 142 to be connected with the first source/drain pattern 160. The first source/drain pattern 160 may be separated from the first gate electrode 130 by the gate dielectric film 120, the first gate spacer 140, and/or the second gate spacer 142.

In some embodiments, the first source/drain pattern 160 may include an epitaxial layer doped with impurities. For example, the first source/drain pattern 160 may include an epitaxial pattern grown by an epitaxial growth method from the first active pattern AP1.

If the first active pattern AP1 is the channel region of a PFET, the first source/drain pattern 160 may include p-type impurities (e.g., boron (B), In, Ga, or Al) or impurities for preventing or limiting the diffusion of the p-type impurities.

The first etch stop film 165 may be formed on the first source/drain pattern 160. The first etch stop film 165 may conformally extend along or otherwise be located relative to the surface profile of the first source/drain pattern 160. In some embodiments, the first etch stop film 165 may further extend along the first surface 102a of the substrate 102. The first etch stop film 165 may include, for example, at least one of silicon nitride (SiN), silicon oxynitride (SiON), silicon oxycarbonitride (SiOCN), silicon boron nitride (SiBN), silicon oxyboronitride (SiOBN), silicon oxycarbide (SiOC), or a combination thereof, but is not limited thereto.

The first interlayer insulating film 190 may be formed on the side surfaces of the gate structure GS. The first interlayer insulating film 190 may be formed to fill at least a portion of the space on the first etch stop film 165. The first interlayer insulating film 190 may include, for example, at least one of silicon oxide, silicon nitride, silicon oxynitride, silicon oxycarbide, silicon boron nitride, silicon carbon boron nitride, silicon oxycarbon nitride, a low-k material with a smaller dielectric constant than silicon oxide, or a combination thereof, but is not limited thereto. The low-k material may include, for example, at least one of flowable oxide (FOX), Torene SilaZene (TOSZ), undoped silica glass (USG), borosilica glass (BSG), phosphosilica glass (PSG), borophosphosilica glass (BPSG), plasma enhanced tetraethyl orthosilicate (PETEOS), fluoride silicate glass (FSG), carbon-doped silicon oxide (CDO), xerogel, aerogel, amorphous fluorinated carbon, organosilicate glass (OSG), parylene, bis-benzocyclobutene (BCB), SiLK, polyimide, porous polymeric material, or a combination thereof.

The second source/drain pattern 260 may be formed on both sides of the gate structure GS. The second source/drain pattern 260 may be connected with the second active pattern AP2. For example, each of the upper bridge patterns 211 and 212 may penetrate the second gate electrode 230, the first gate spacer 140, and the second gate spacer 142 to be connected with the second source/drain pattern 260. The second source/drain pattern 260 may be separated from the second gate electrode 230 by the gate dielectric film 120, the first gate spacer 140, and/or the second gate spacer 142.

In some embodiments, the second source/drain pattern 260 may include an epitaxial layer doped with impurities. For example, the second source/drain pattern 260 may include an epitaxial pattern grown by an epitaxial growth method from the second active pattern AP2.

If the second active pattern AP2 is the channel region of an NFET, the second source/drain pattern 260 may include n-type impurities (e.g., P, Sb, or As) or impurities for preventing or limiting the diffusion of the n-type impurities.

The second etch stop film 265 may be formed on the second source/drain pattern 260. The second etch stop film 265 may conformally extend along or otherwise be located relative to the surface profile of the second source/drain pattern 260. In some embodiments, the second etch stop film 265 may further extend along the upper surface of the first interlayer insulating film 190. The second etch stop film 265 may include, for example, at least one of SiN, SiON, SiOCN, SiBN, SiOBN, SiOC, or a combination thereof, but is not limited thereto.

The second interlayer insulating film 290 may be formed on the side surfaces of the gate structure GS. The second interlayer insulating film 290 may be formed to fill at least a portion of the space on the second etch stop film 265. The second interlayer insulating film 290 may include, for example, at least one of silicon oxide, silicon nitride, silicon oxynitride, silicon oxycarbide, silicon boron nitride, silicon carbon boron nitride, silicon oxycarbon nitride, the above-described low-k material, or a combination thereof, but is not limited thereto.

The first via structure TV1 may extend in the first direction Z across the first and second regions I and II. The first via structure TV1 may be disposed on one side of the gate structure GS. For example, as illustrated in FIG. 7A, a via hole CH extending in the first direction Z may be formed through the first etch stop film 165, the first interlayer insulating film 190, the second etch stop film 265, and the second interlayer insulating film 290. The first via structure TV1 may fill at least a portion of the via hole CH. In some embodiments, the via hole CH may further penetrate the substrate 102.

In some embodiments, the first via structure TV1 may be spaced apart from the first and second source/drain patterns 160 and 260 in the third direction Y.

In some embodiments, the width of the first via structure TV1 (or the via hole CH) may increase toward the first direction Z. Here, the term “width” refers to the width in a horizontal direction parallel to the first surface 102a (e.g., in the second direction X or the third direction Y), which may result or be due to managing the characteristics of the etching process for forming the via hole CH.

The first via structure TV1 may include a first via pattern TVa, a first liner insulating film 281b, and a second via pattern TVb. The first and second via patterns TVa and TVb may be sequentially stacked in the first direction Z. The first liner insulating film 281b may be formed on the upper surface of the first via pattern TVa and extend along the side surface of the second via pattern TVb. For example, the first liner insulating film 281b may conformally extend along or otherwise be located relative to the surface profile of the outer side surface of the second via pattern TVb.

Specifically, as illustrated in FIG. 7A, the via hole CH may include a first sub-hole CHa and a second sub-hole CHb sequentially arranged in the first direction Z. For example, the first sub-hole CHa may correspond to a lower portion of the via hole CH, and the second sub-hole CHb may correspond to an upper portion of the via hole CH. The first via pattern TVa may fill at least a portion of the first sub-hole CHa. The first liner insulating film 281b may extend along the side surface of the second sub-hole CHb. The second via pattern TVb may be formed on the inner surface of the first liner insulating film 281b. The second via pattern TVb may fill at least a portion of the remaining second sub-hole CHb after the formation of the first liner insulating film 281b. The second via pattern TVb may penetrate a lower portion of the first liner insulating film 281b to be connected with the first via pattern TVa.

A boundary or interface may exist between the first and second via patterns TVa and TVb. For example, as illustrated in FIG. 7A, the boundary between the first and second via patterns TVa and TVb may extend along a horizontal plane parallel to the first surface 102a (e.g., the XY plane). In some embodiments, the lowermost surface of the first liner insulating film 281b may be disposed on the same plane as the boundary between the first and second via patterns TVa and TVb. In some embodiments, the boundary between the first and second via patterns TVa and TVb may include an upwardly concave curved surface.

In some embodiments, the first via pattern TVa may include a first seam Sa. The first seam Sa may extend longitudinally in the first direction Z. The first seam Sa may correspond to the boundary of the first via pattern TVa formed as the first via pattern TVa fills a relatively narrow first sub-hole CHa. The first seam Sa may be spaced apart from the lower surface of the first via pattern TVa in the first direction Z. The first seam Sa may extend to the boundary between the first and second via patterns TVa and TVb. For example, the first seam Sa may contact the lower surface of the second via pattern TVb.

In some embodiments, the second via pattern TVb may include a second seam Sb. The second seam Sb may extend longitudinally in the first direction Z. The second seam Sb may correspond to the boundary of the second via pattern TVb formed as the second via pattern TVb fills a relatively narrow second sub-hole CHb. The second seam Sb may be spaced apart from the upper surface of the first via pattern TVa in the first direction Z.

Heights Ha and Hb of the first and second via patterns TVa and TVb in the first direction Z are illustrated as being the same, but this is presented merely for exemplary purposes. Alternatively, the heights Ha of the first and second via patterns TVa and TVb may differ.

In some embodiments, the widths of the first and second sub-holes CHa and CHb may each increase toward the first direction Z. In some embodiments, the width of the second sub-hole CHb may be greater than or equal to the width of the first sub-hole CHa. In some embodiments, the side surfaces of the first and second sub-holes CHa and CHb may be continuously connected without a step. For example, as illustrated, at the horizontal plane including the boundary between the first and second sub-holes CHa and CHb, the widths of the first and second sub-holes CHa and CHb may be the same. In this specification, “the same” refers not only to being completely identical but also includes slight variations that may occur due to process margins or the like.

In some embodiments, at the boundary between the first and second via patterns TVa and TVb, a width Wa of the first via pattern TVa may be greater than a width Wb of the second via pattern TVb.

In some embodiments, at the boundary between the first and second via patterns TVa and TVb, a thickness T1b of the first liner insulating film 281b may be greater than or equal to the difference between the widths Wa and Wb of the first and second via patterns TVa and TVb, i.e., (Wa−Wb). For example, as illustrated in FIG. 7A, the thickness T1b of the first liner insulating film 281b may be equal to (Wa−Wb). In this case, the side surfaces of the first and second sub-holes CHa and CHb may be continuously connected without a step.

The first and second via patterns TVa and TVb may each include a conductive material, for example, at least one of titanium (Ti), tantalum (Ta), tungsten (W), nickel (Ni), cobalt (Co), platinum (Pt), Al, ruthenium (Ru), silver (Ag), gold (Au), an alloy thereof, or a nitride thereof, but are not limited thereto.

In some embodiments, the first via pattern TVa may include a first barrier conductive film 282a and a first filling conductive film 284a, which are sequentially stacked in the first sub-hole CHa. The first barrier conductive film 282a may include a metal or a metal nitride for preventing or limiting the diffusion of a metal element included in the first filling conductive film 284a. The first filling conductive film 284a may fill the space on the first barrier conductive film 282a. In some embodiments, the first filling conductive film 284a may include the first seam Sa.

In some embodiments, the second via pattern TVb may include a second barrier conductive film 282b and a second filling conductive film 284b, which are sequentially stacked on the first via pattern TVa and the first liner insulating film 281b. The second barrier conductive film 282b may include a metal or a metal nitride for preventing or limiting the diffusion of a metal element included in the second filling conductive film 284b. The second filling conductive film 284b may fill the space on the second barrier conductive film 282b. In some embodiments, the second filling conductive film 284b may include the second seam Sb.

The first and second barrier conductive films 282a and 282b may each include, for example, at least one of Ti, Ta, W, Ni, Co, Pt, an alloy thereof, or a nitride thereof, but are not limited thereto.

The first and second filling conductive films 284a and 284b may each include, for example, at least one of Al, copper (Cu), W, molybdenum (Mo), Co, Ru, or an alloy thereof, but are not limited thereto.

The first liner insulating film 281b may include, for example, at least one of silicon oxide, silicon nitride, silicon oxynitride, silicon oxycarbide, silicon boron nitride, silicon carbon boron nitride, silicon oxycarbonitride, or a combination thereof, but is not limited thereto. For example, the first liner insulating film 281b may include a silicon nitride film.

The second via structure TV2 may extend in the first direction Z across the first and second regions I and II. The second via structure TV2 may be disposed on the other side of the gate structure GS relative to TV1. The second via structure TV2 may include the first via pattern TVa, the first liner insulating film 281b, and the second via pattern TVb, which have been described above in connection with the first via structure TV1. The second via structure TV2 may be similar to the first via structure TV1, and thus, a detailed description thereof will be omitted.

The first and second frontside source/drain contacts FC1 and FC2 may be disposed in the second region II. The first frontside source/drain contact FC1 may be disposed on one side of the gate structure GS, and the second frontside source/drain contact FC2 may be disposed on the other side of the gate structure GS. The first and second frontside source/drain contacts FC1 and FC2 may each be connected with the second source/drain pattern 260. For example, each of the first and second frontside source/drain contacts FC1 and FC2 may penetrate the second interlayer insulating film 290 and the second etch stop film 265 to contact the upper surface of the second source/drain pattern 260.

The first frontside source/drain contact FC1 may connect the second source/drain pattern 260 and the first via structure TV1. For example, the first frontside source/drain contact FC1 may extend in the second direction X to contact the side surface of the first via structure TV1. In some embodiments, as illustrated in FIG. 5, the first frontside source/drain contact FC1 may penetrate the first liner insulating film 281b to contact the second via pattern TVb of the first via structure TV1.

The second frontside source/drain contact FC2 may connect the second source/drain pattern 260 and the second via structure TV2. For example, the second frontside source/drain contact FC2 may extend in the second direction X to contact the side surface of the second via structure TV2. In some embodiments, as illustrated in FIG. 6, the second frontside source/drain contact FC2 may penetrate the first liner insulating film 281b to contact the second via pattern TVb of the second via structure TV2.

In some embodiments, each of the first and second frontside source/drain contacts FC1 and FC2 may include a third barrier conductive film 272 and a third filling conductive film 274, which are sequentially stacked. The third barrier conductive film 272 may include a metal or a metal nitride for preventing or limiting the diffusion of a metal element included in the third filling conductive film 274. The third filling conductive film 274 may fill the space on the third barrier conductive film 272.

In some embodiments, each of the first and second frontside source/drain contacts FC1 and FC2 may further include a silicide film 271. The silicide film 271 may be formed by the reaction of a semiconductor element included in the second source/drain pattern 260 (e.g., Si) and a metal element. The silicide film 271 may include, for example, a metal silicide such as nickel silicide, cobalt silicide, tungsten silicide, titanium silicide, niobium silicide, or tantalum silicide, but is not limited thereto.

The frontside wiring structure FW may be formed on the first surface 102a of the substrate 102. For example, the frontside wiring structure FW may be formed on the upper surface of the second interlayer insulating film 290. The frontside wiring structure FW may include a frontside wiring insulating film 310 and frontside wiring patterns FM within the frontside wiring insulating film 310. The quantities, arrangements, and numbers of layers of the frontside wiring insulating film 310 and the frontside wiring patterns FM are presented merely for exemplary purposes and are not limited to those illustrated. Although not specifically illustrated, each of the frontside wiring patterns FM may include a barrier conductive film and a filling conductive film.

In some embodiments, the frontside wiring patterns FM may include a first frontside wiring pattern 331, a second frontside wiring pattern 332, and a third frontside wiring pattern 333, which are sequentially arranged in the third direction Y. The first, second, and third frontside wiring patterns 331, 332, and 333 may each extend in the second direction X and may be spaced apart from one another in the third direction Y.

The frontside wiring structure FW may provide signal lines and/or power lines for electronic devices (e.g., FETs) on the first surface 102a of the substrate 102.

For example, as illustrated in FIG. 4, a first frontside contact pattern 321 may be formed on the second gate electrode 230. The first frontside contact pattern 321 may penetrate the gate capping film 150 to connect the second gate electrode 230 and the first frontside wiring pattern 331. The first frontside wiring pattern 331 may be provided as the input signal Vᵢₙ of the inverter illustrated in FIG. 1.

Additionally, for example, as illustrated in FIG. 3, a second frontside contact pattern 322 may be formed on the second frontside source/drain contact FC2. The second frontside contact pattern 322 may connect the second frontside source/drain contact FC2 and the second frontside wiring pattern 332. The second frontside wiring pattern 332 may be provided as the output signal Vₒᵤₜ of the inverter illustrated in FIG. 1.

The first and second backside source/drain contacts BC1 and BC2 may be disposed in the first region I. The first backside source/drain contact BC1 may be disposed on one side of the gate structure GS, and the second backside source/drain contact BC2 may be disposed on the other side of the gate structure GS. The first and second backside source/drain contacts BC1 and BC2 may each be connected with the first source/drain pattern 160. For example, each of the first and second backside source/drain contacts BC1 and BC2 may penetrate the substrate 102 to contact the lower surface of the first source/drain pattern 160.

The second backside source/drain contact BC2 may connect the first source/drain pattern 160 and the second via structure TV2. For example, the second backside source/drain contact BC2 may extend in the second direction X to contact the lower surface of the second via structure TV2. Through this, the second via structure TV2 may connect the first source/drain pattern 160 and the second source/drain pattern 260.

The backside wiring structure BW may be formed on the second surface 102b of the substrate 102. For example, the backside wiring structure BW may be formed on the lower surface of a backside insulating film 400. The backside wiring structure BW may include a backside wiring insulating film 410 and backside wiring patterns BM within the backside wiring insulating film 410. The quantities, arrangements, and numbers of layers of the backside wiring insulating film 410 and the backside wiring patterns BM are presented merely for exemplary purposes and are not limited to those illustrated. Although not specifically illustrated, each of the backside wiring patterns BM may include a barrier conductive film and a filling conductive film.

In some embodiments, the backside wiring patterns BM may include a first backside wiring pattern 431 and a second backside wiring pattern 432, which are sequentially arranged in the third direction Y. The first and second backside wiring patterns 431 and 432 may each extend in the second direction X and may be spaced apart from one another in the third direction Y.

The backside wiring structure BW may provide signal lines and/or power lines for electronic devices (e.g., FETs) on the second surface 102b of the substrate 102.

For example, different power supply voltages may be applied to the first backside wiring pattern 431 and the second backside wiring pattern 432. For example, a first power supply voltage (e.g., V_{SS}) may be applied to the first backside wiring pattern 431, and a second power supply voltage (e.g., V_{DD}), different from the first power supply voltage, may be applied to the second backside wiring pattern 432.

The first via structure TV1 may be connected with the first backside wiring pattern 431. For example, a first backside contact pattern 421 may be formed to extend in the first direction Z, connecting the first via structure TV1 to the first backside wiring pattern 431. Through this, the first power supply voltage (e.g., V_{SS}) may be applied to the second source/drain pattern 260 on one side of the gate structure GS.

The first backside source/drain contact BC1 may connect the first source/drain pattern 160 and the second backside wiring pattern 432. For example, a second backside contact pattern 422 may be formed to extend in the first direction Z, connecting the first source/drain pattern 160 and the second backside wiring pattern 432. Through this, the second power supply voltage (e.g., V_{DD}) may be applied to the first source/drain pattern 160 on one side of the gate structure GS.

The second backside source/drain contact BC2 may connect the first source/drain pattern 160 and the second via structure TV2. For example, the second backside source/drain contact BC2 may extend in the second direction X to contact the lower surface of the second via structure TV2. Through this, the first source/drain pattern 160 on one side of the gate structure GS and the second source/drain pattern 260 on the other side of the gate structure GS may be electrically connected.

In some embodiments, the backside insulating film 400 may be formed on the second surface 102b of the substrate 102. Each of the first and second backside source/drain contacts BC1 and BC2 may penetrate the backside insulating film 400 and the substrate 102 to be connected with the first source/drain pattern 160.

For example, the first backside source/drain contact BC1 may include a first direct contact DC1 and a first connection contact MC1. The first direct contact DC1 may penetrate the substrate 102. The first direct contact DC1 may be connected with the lower surface of the first source/drain pattern 160 on one side of the gate structure GS. The first connection contact MC1 may be formed within the backside insulating film 400. The first connection contact MC1 may extend in the second direction X to connect the first direct contact DC1 and the second backside contact pattern 422.

For example, the second backside source/drain contact BC2 may include a second direct contact DC2 and a second connection contact MC2. The second direct contact DC2 may penetrate the substrate 102. The second direct contact DC2 may be connected with the lower surface of the first source/drain pattern 160 on the other side of the gate structure GS. The second connection contact MC2 may be formed within the backside insulating film 400. The second connection contact MC2 may extend in the second direction X to connect the second direct contact DC2 and the second via structure TV2.

In some embodiments, a third connection contact MC3 may be formed within the backside insulating film 400. The third connection contact MC3 may extend in the first direction Z to connect the first via structure TV1 and the first backside contact pattern 421.

In some embodiments, each of the first and second direct contacts DC1 and DC2 may include a fourth barrier conductive film 472 and a fourth filling conductive film 474, which are sequentially stacked. The fourth barrier conductive film 472 may include a metal or metal nitride to prevent or limiting diffusion of a metal element included in the fourth filling conductive film 474. The fourth filling conductive film 474 may fill the space on the fourth barrier conductive film 472.

In some embodiments, each of the first, second, and third connection contacts MC1, MC2, and MC3 may include a fifth barrier conductive film 482 and a fifth filling conductive film 484, which are sequentially stacked. The fifth barrier conductive film 482 may include a metal or metal nitride to prevent or limiting diffusion of a metal element included in the fifth filling conductive film 484. The fifth filling conductive film 484 may fill the space on the fifth barrier conductive film 482.

As semiconductor devices become increasingly integrated, individual circuit patterns are being miniaturized to implement more devices in the same area. To facilitate this, the contemplated semiconductor devices may utilize the illustrated stacking of multi-gate transistors, where in the multi-gate transistors in an upper region (e.g., the second region II) are stacked on multi-gate transistors in a lower region (e.g., the first region I),

However, some semiconductor devices including multi-gate transistors may face challenges in improving integration density due to the complexity of the circuit patterns. For example, to connect the lower region and the upper region, tall vias extending across both regions may be required. However, due to the high aspect ratio of the tall vias, not-open failure may occur where the tall vias are not fully formed. To prevent this, the critical dimension of the tall vias may be increased, but this increased critical dimension can cause a short with adjacent components (e.g., source/drain patterns).

The semiconductor device according to some embodiments may provide improved integration density and performance for stacked multi-gate transistors by connecting the first and second regions I and II using the first via structure TV1 and/or the second via structure TV2, e.g., using two or more via patterns.

For example, as described above, the first via structure TV1 may include the first and second via patterns TVa and TVb, which are sequentially stacked in the first direction Z. The aspect ratio of each of the first and second via patterns TVa and TVb may each be relatively smaller compared to the overall aspect ratio of the first via structure TV1, thereby effectively preventing or limiting not-open failure.

Additionally, for example, as described above, the first via structure TV1 may include the first liner insulating film 281b, selectively formed along the side surface of the second via pattern TVb. The first liner insulating film 281b may prevent or limiting a short with adjacent components (e.g., the second source/drain pattern 260) in the upper portion of the first via structure TV1 where the critical dimension is relatively large.

Referring to FIGS. 1 to 6 and 7B, in the semiconductor device according to some embodiments, the thickness T1b of the first liner insulating film 281b is greater than the thickness T2a of the first barrier conductive film 282a. For example, the first liner insulating film 281b may be in contact with both the upper surface of the first barrier conductive film 282a and the upper surface of the first filling conductive film 284a.

Referring to FIGS. 1 to 6 and 7C, in the semiconductor device according to some embodiments, the thickness T1b of the first liner insulating film 281b is smaller than the thickness T2a of the first barrier conductive film 282a. For example, the second barrier conductive film 282b may be in contact with both the upper surface of the first barrier conductive film 282a and the upper surface of the first filling conductive film 284a.

Referring to FIGS. 1 to 6 and 7D, in the semiconductor device according to some embodiments, a width HWb of the second sub-hole CHb is greater than a width HWa of the first sub-hole CHa.

For example, as illustrated, at the horizontal plane including the boundary between the first and second via patterns TVa and TVb, the width HWb of the second sub-hole CHb may be greater than the width HWa of the first sub-hole CHa. In this case, the side surfaces of the first and second sub-holes CHa and CHb may be discontinuously connected with a step.

In some embodiments, the thickness T1b of the first liner insulating film 281b may be greater than or equal to the difference between the widths HWa and HWb of the first and second sub-holes CHa and CHb.

Referring to FIGS. 1 to 6 and 7E, in the semiconductor device according to some embodiments, the first via structure TV1 may further include a second liner insulating film 281a.

The second liner insulating film 281a may extend along the side surface of the first via pattern TVa. For example, the second liner insulating film 281a may conformally extend along or otherwise be located relative to the profile of the outer side surface of the first via pattern TVa. The second liner insulating film 281a may extend along the side surface of the first sub-hole CHa. The first via pattern TVa may be formed on the inner surface of the second liner insulating film 281a. The first via pattern TVa may fill at least a portion of the remaining first sub-hole CHa after the formation of the second liner insulating film 281a.

In some embodiments, a thickness T1a of the second liner insulating film 281a and a thickness T1b of the first liner insulating film 281b may differ. In some embodiments, the thickness T1b of the first liner insulating film 281b may be greater than the thickness T1a of the second liner insulating film 281a.

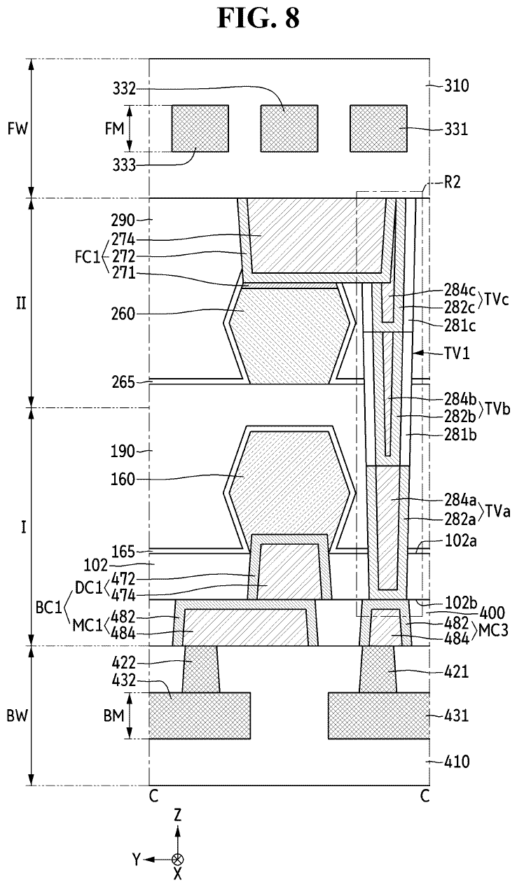

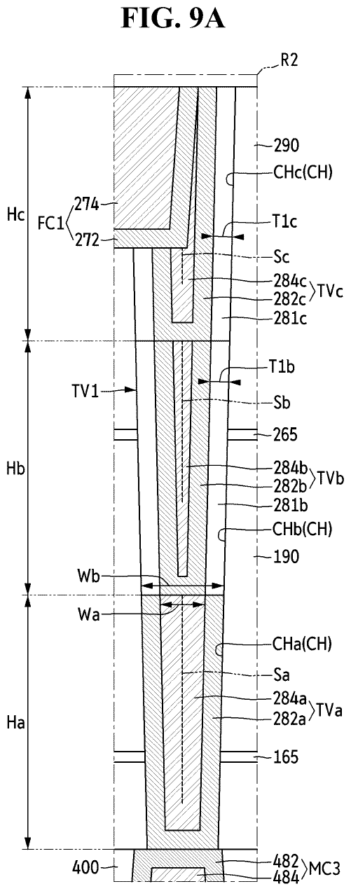

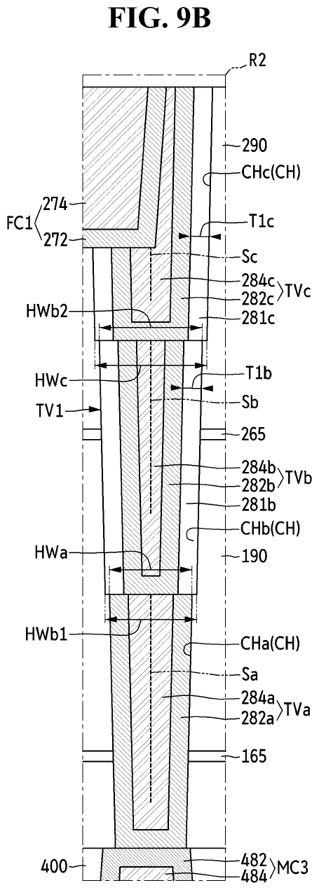

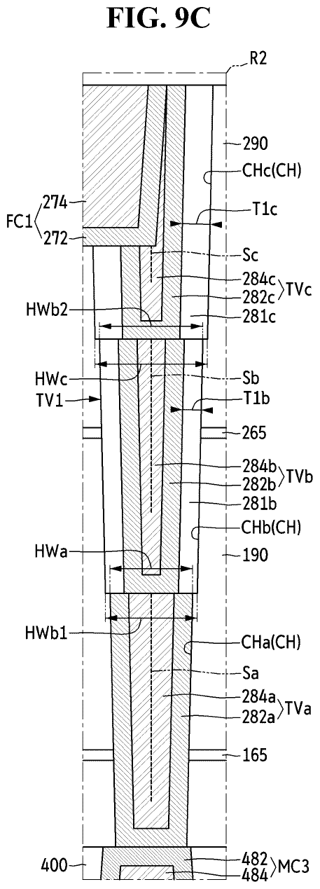

FIG. 8 is a cross-sectional view for explaining a semiconductor device according to some embodiments. For reference, FIG. 8 is a cross-sectional view taken along line C-C of FIG. 2. FIGS. 9A through 9C are various enlarged views for explaining region R2 of FIG. 8. For the convenience of description, overlapping content with FIGS. 1 through 7E, which has been described above, will be briefly explained or omitted.

Referring to FIGS. 1, 2, 8, and 9A through 9C, a first via structure TV1 in the semiconductor device according to some embodiments may further include a third liner insulating film 281c and a third via pattern TVc.

A first via pattern TVa, a second via pattern TVb, and the third via pattern TVc may be sequentially stacked in a first direction Z. The third liner insulating film 281c may be formed on the upper surface of the second via pattern TVb and may extend along the side surface of the third via pattern TVc. For example, the third liner insulating film 281c may conformally extend along or otherwise be located relative to the profile of the outer side surface of the third via pattern TVc.

Specifically, as illustrated in FIG. 9A, a via hole CH may include a first sub-hole CHa, a second sub-hole CHb, and a third sub-hole CHc, which are sequentially arranged in the first direction Z. For example, the first sub-hole CHa may correspond to a lower portion of the via hole CH, the second sub-hole CHb may correspond to a middle portion of the via hole CH, and the third sub-hole CHc may correspond to an upper portion of the via hole CH. The third liner insulating film 281c may extend along the side surface of the third sub-hole CHc. The third via pattern TVc may be formed on the inner surface of the third liner insulating film 281c. The third via pattern TVc may fill at least a portion of the remaining third sub-hole CHc after the formation of the third liner insulating film 281c. The third via pattern TVc may penetrate a lower portion of the third liner insulating film 281c to be connected with the second via pattern TVb.

A boundary may exist between the second and third via patterns TVb and TVc. For example, as illustrated in FIG. 9A, the boundary between the second and third via patterns TVb and TVc may extend along a horizontal plane parallel to a first surface 102a (e.g., the XY plane). In some embodiments, the lowermost surface of the third liner insulating film 281c may be disposed on the same plane as the boundary between the second and third via patterns TVb and TVc. In some embodiments, the boundary between the second and third via patterns TVb and TVc may include an upwardly concave curved surface.

In some embodiments, the third via pattern TVc may include a third seam Sc. The third seam Sc may extend longitudinally in the first direction Z. The third seam Sc may correspond to the boundary of the third via pattern TVc formed as the third via pattern TVc fills a relatively narrow third sub-hole CHc. The third seam Sc may be spaced apart from the upper surface of the second via pattern TVb in the first direction Z.

Heights Ha, Hb, and Hc of the first, second, and third via patterns TVa, TVb, and TVc in the first direction Z are illustrated as being the same, but this is presented merely for exemplary purposes. Optionally, the heights Ha, Hb, and Hc may differ.

In some embodiments, the width of the third sub-hole CHc may increase toward the first direction Z. In some embodiments, the width of the third sub-hole CHc may be greater than or equal to the width of the second sub-hole CHb. In some embodiments, the side surfaces of the second and third sub-holes CHb and CHc may be continuously connected without a step. For example, as illustrated in FIG. 9A, at the horizontal plane including the boundary between the second and third via patterns TVb and TVc, the widths of the second and third sub-holes CHb and CHc may be the same.

In some embodiments, the third via pattern TVc may include a sixth barrier conductive film 282c and a sixth filling conductive film 284c, which are sequentially stacked within the third sub-hole CHc. The sixth barrier conductive film 282c may include a metal or a metal nitride for preventing or limiting the diffusion of a metal element included in the sixth filling conductive film 284c. The sixth filling conductive film 284c may fill the space on the sixth barrier conductive film 282c. In some embodiments, the sixth filling conductive film 284c may include the third seam Sc.

The third liner insulating film 281c may include the same insulating material as, or a different insulating material from, the first liner insulating film 281b.

A thickness T1b of the first liner insulating film 281b and a thickness T1c of the third liner insulating film 281c are illustrated as being the same, but this is presented merely for exemplary purposes. The thicknesses T1b and T1c may differ.

Referring to FIGS. 1, 2, 8, and 9B through 9C, in the semiconductor device according to some embodiments, the width of the second sub-hole CHb may be greater than the width of the first sub-hole CHa, and the width of the third sub-hole CHc may be greater than the width of the second sub-hole CHb.

For example, as illustrated, at the horizontal plane including the boundary between the first and second via patterns TVa and TVb, a width HWb1 of the second sub-hole CHb may be greater than a width HWa of the first sub-hole CHa. In this case, the side surfaces of the first and second sub-holes CHa and CHb may be discontinuously connected with a step.

Similarly, as illustrated, at the horizontal plane including the boundary between the second and third via patterns TVb and TVc, a width HWc of the third sub-hole CHc may be greater than a width HWb2 of the second sub-hole CHb. In this case, the side surfaces of the second and third sub-holes CHb and CHc may be discontinuously connected with a step.

Referring to FIGS. 1, 2, 8, and 9C, in a semiconductor device according to some embodiments, the thickness T1c of the third liner insulating film 281c may be greater than the thickness T1b of the first liner insulating film 281b.

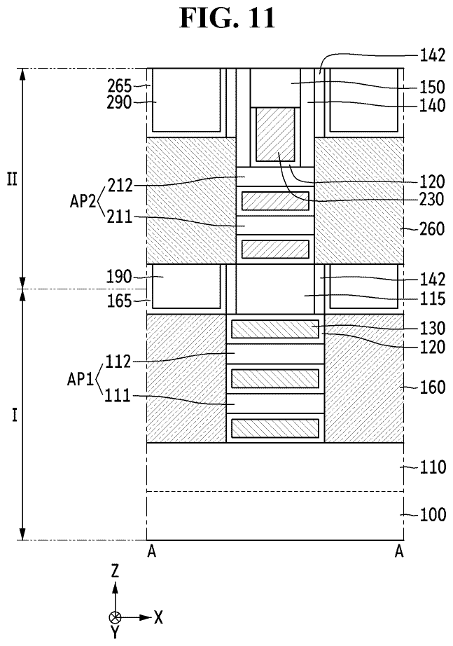

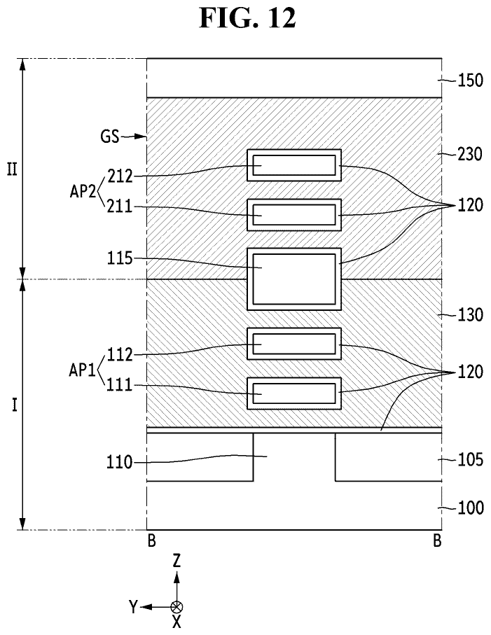

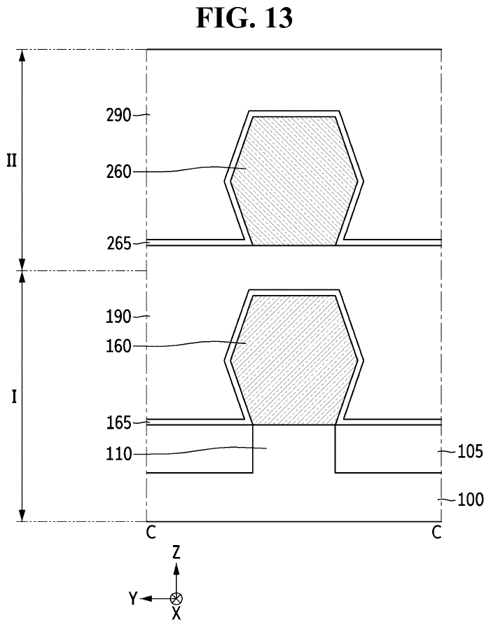

A semiconductor device according to some embodiments will hereinafter be described with reference to FIGS. 1 through 24.

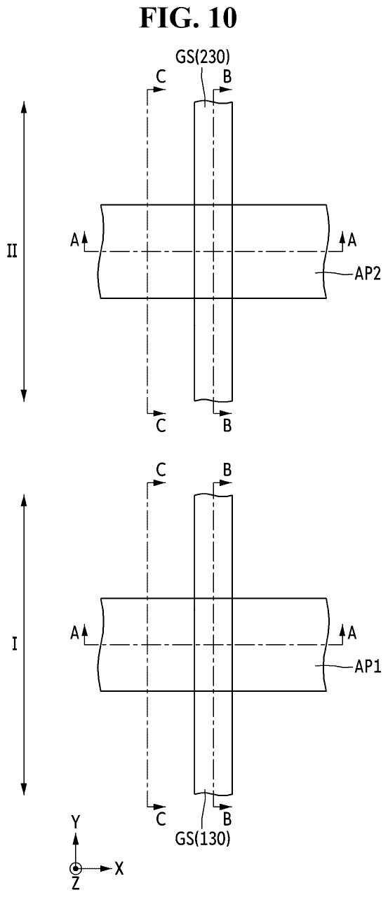

FIGS. 10 through 24 are diagrams illustrating intermediate steps of a method for manufacturing a semiconductor device according to some embodiments. For convenience of description, overlapping content with FIGS. 1 through 9C, which has been described above, will be briefly explained or omitted.

Referring to FIGS. 10 through 13, a first active pattern AP1, an intermediate insulating pattern 115, a second active pattern AP2, a gate structure GS, a first source/drain pattern 160, a first etch stop film 165, a first interlayer insulating film 190, a second source/drain pattern 260, a second etch stop film 265, and a second interlayer insulating film 290 are formed on a base substrate 100.

The base substrate 100 may be bulk silicon or SOI. Alternatively, the base substrate 100 may be an Si substrate or may include other materials, for example, SiGe, SGOI, indium antimonide, a lead telluride compound, indium arsenide, indium phosphide, gallium arsenide, or gallium antimonide.

In some embodiments, a fin pattern 110 and a field insulating film 105 may be formed on the base substrate 100. The fin pattern 110 may protrude from the upper surface of the base substrate 100 and extend in a second direction X. The field insulating film 105 may cover at least a portion of the side surface of the fin pattern 110.

The first active pattern AP1 may be spaced apart from the fin pattern 110 in a first direction Z. The intermediate insulating pattern 115 may be spaced apart from the first active pattern AP1 in the first direction Z. The second active pattern AP2 may be spaced apart from the intermediate insulating pattern 115 in the first direction Z.

The gate structure GS may intersect the first and second active patterns AP1 and AP2. The gate structure GS may include a gate dielectric film 120, a first gate electrode 130, a second gate electrode 230, a first gate spacer 140, a second gate spacer 142, and a gate capping film 150.

The first source/drain pattern 160 may be formed on both sides of the gate structure GS. The first source/drain pattern 160 may be connected with the first active pattern AP1. The first etch stop film 165 may be formed on the first source/drain pattern 160. The first interlayer insulating film 190 may be formed on the side surfaces of the gate structure GS. The first interlayer insulating film 190 may be formed to fill at least a portion of the space on the first etch stop film 165.

The second source/drain pattern 260 may be formed on both sides of the gate structure GS. The second source/drain pattern 260 may be connected to the second active pattern AP2. The second etch stop film 265 may be formed on the second source/drain pattern 260. The second interlayer insulating film 290 may be formed on the side surfaces of the gate structure GS. The second interlayer insulating film 290 may be formed to fill at least a portion of the space on the second etch stop film 265.

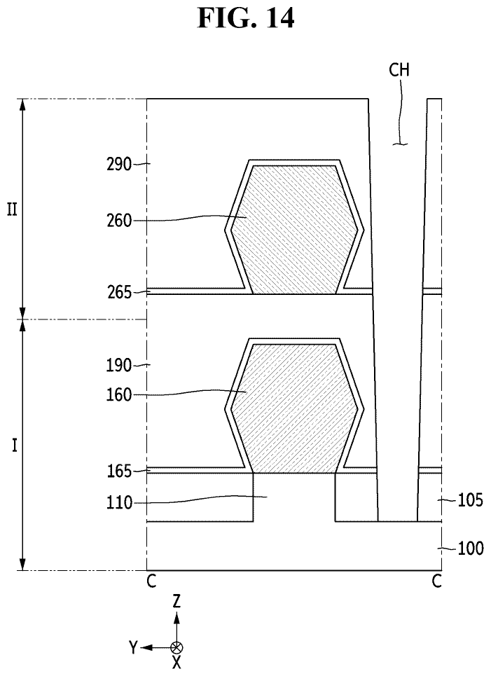

Referring to FIG. 14, a via hole CH is formed.

The via hole CH may extend in the first direction Z through the first etch stop film 165, the first interlayer insulating film 190, the second etch stop film 265, and the second interlayer insulating film 290. In some embodiments, the via hole CH may further penetrate the field insulating film 105.

In some embodiments, the via hole CH may be spaced apart from the first and second source/drain patterns 160 and 260 in the third direction Y.

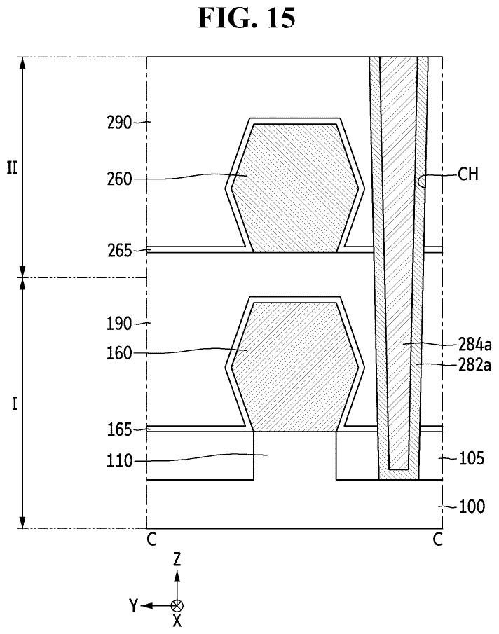

Referring to FIG. 15, a first barrier conductive film 282a and a first filling conductive film 284a are formed within the via hole CH.

The first barrier conductive film 282a may conformally extend along or otherwise be located relative to the profile of the side surface and the lower surface of the via hole CH. The first filling conductive film 284a may fill at least a portion of the remaining space after the formation of the first barrier conductive film 282a.

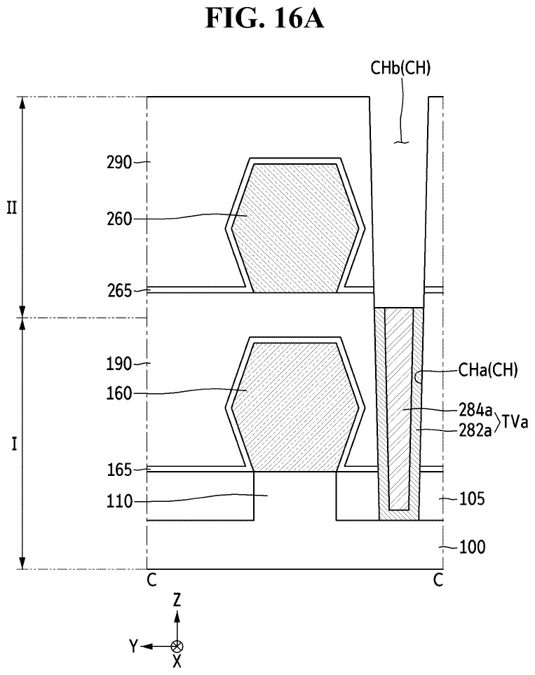

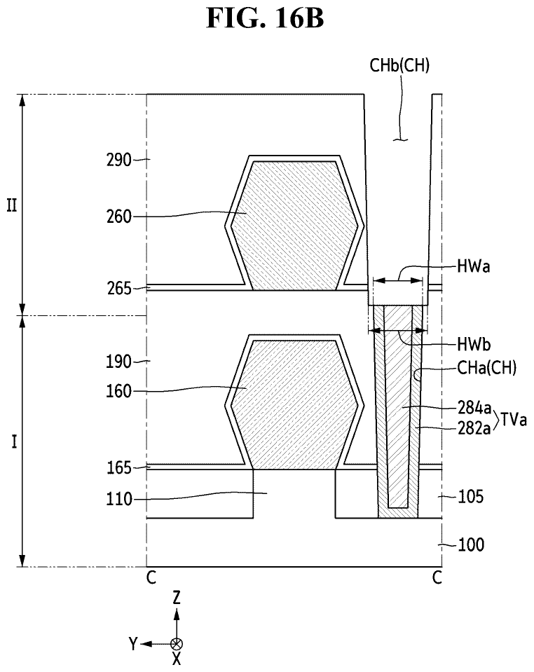

Referring to FIGS. 16A and 16B, a first recess process is performed on the first barrier conductive film 282a and the first filling conductive film 284a.

As the first recess process is performed, upper portions of the first barrier conductive film 282a and the first filling conductive film 284a may be removed. For example, the portions of the first barrier conductive film 282a and the first filling conductive film 284a within the second sub-hole CHb may be removed, while the portions of the first barrier conductive film 282a and the first filling conductive film 284a within the first sub-hole CHa may remain. Through this, a first via pattern TVa filling the first sub-hole CHa may be provided.

In some embodiments, after the first recess process, as illustrated in FIG. 16A, the side surfaces of the first and second sub-holes CHa and CHb may be continuously connected without a step. For example, at the horizontal plane including the upper surface of the first via pattern TVa, the widths of the first and second sub-holes CHa and CHb may be the same.

In some embodiments, after the first recess process, as illustrated in FIG. 16B, a width HWb of the second sub-hole CHb may be greater than a width HWa of the first sub-hole CHa. For example, at the horizontal plane including the upper surface of the first via pattern TVa, the width HWb of the second sub-hole CHb may be greater than the width HWa of the first sub-hole CHa. For example, during the first recess process, a portion of the first interlayer insulating film 190, a portion of the second etch stop film 265, and/or a portion of the second interlayer insulating film 290 may be removed. In this case, the side surfaces of the first and second sub-holes CHa and CHb may be discontinuously connected with a step.

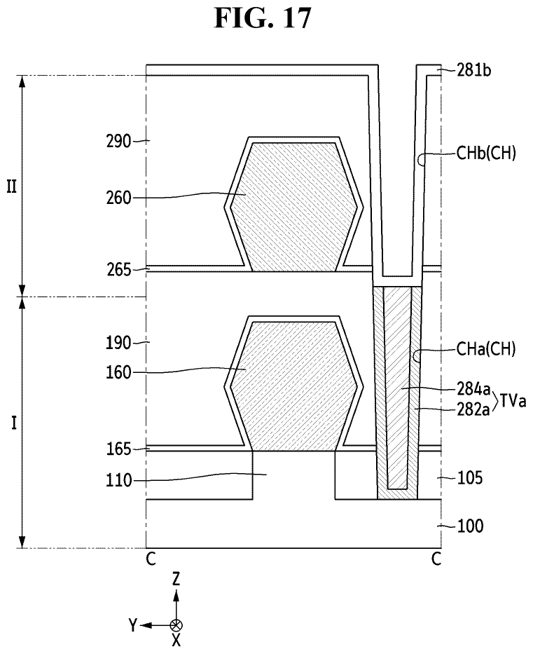

Referring to FIG. 17, a first liner insulating film 281b is formed within the second sub-hole CHb.

The first liner insulating film 281b may conformally extend along or otherwise be located relative to the upper surface of the second interlayer insulating film 290, the side surface of the second sub-hole CHb, and the upper surface of the first via pattern TVa.

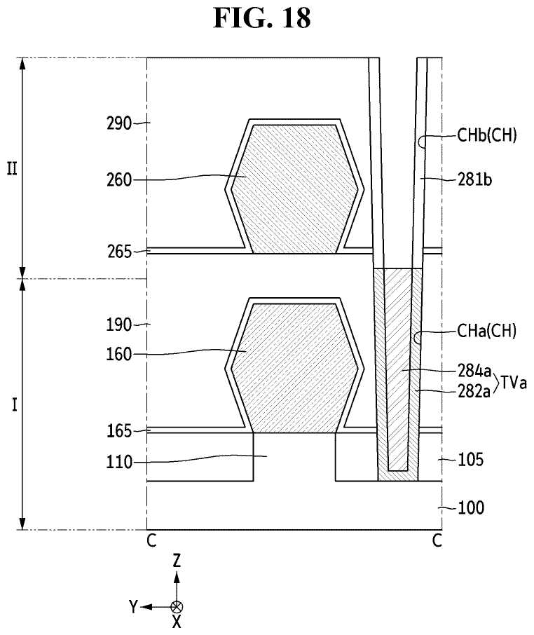

Referring to FIG. 18, a second recess process is performed on the first liner insulating film 281b.

As the second recess process is performed, a portion of the first liner insulating film 281b extending along the horizontal plane may be removed. For example, a portion of the first liner insulating film 281b extending along the upper surfaces of the second interlayer insulating film 290 and the first via pattern TVa may be removed. Through this, the upper surface of the first via pattern TVa may be exposed from the second sub-hole CHb.

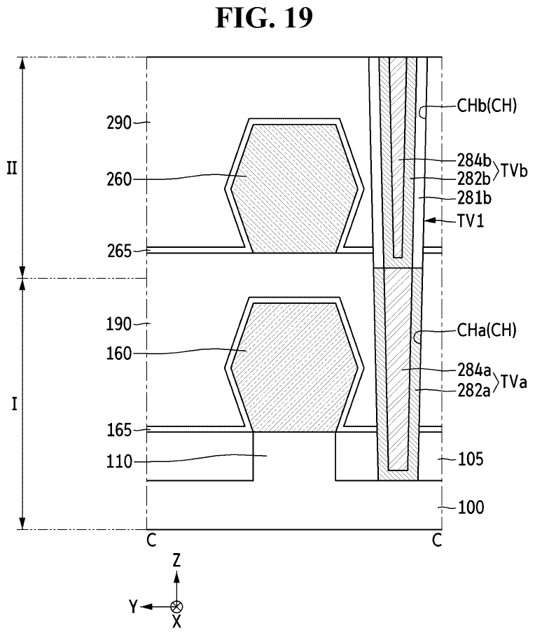

Referring to FIG. 19, a second barrier conductive film 282b and a second filling conductive film 284b are formed on the first via pattern TVa and the first liner insulating film 281b.

The second barrier conductive film 282b may conformally extend along or otherwise be located relative to the profile of the inner surface of the first liner insulating film 281b and the upper surface of the first via pattern TVa. The second filling conductive film 284b may fill at least a portion of the remaining second sub-hole CHb after the formation of the first liner insulating film 281b and the second barrier conductive film 282b. Through this, a second via pattern TVb filling the second sub-hole CHb may be provided. Additionally, a first via structure TV1, including the first via pattern TVa, the first liner insulating film 281b, and the second via pattern TVb, may be formed.

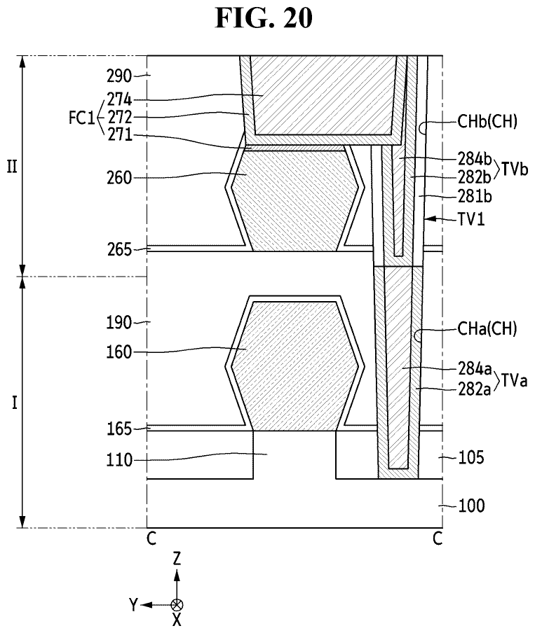

Referring to FIG. 20, a first frontside source/drain contact FC1 is formed.

The first frontside source/drain contact FC1 may extend in the second direction X to connect the second source/drain pattern 260 and the first via structure TV1. For example, the first frontside source/drain contact FC1 may contact the upper surface of the second source/drain pattern 260 and the side surface of the first via structure TV1.

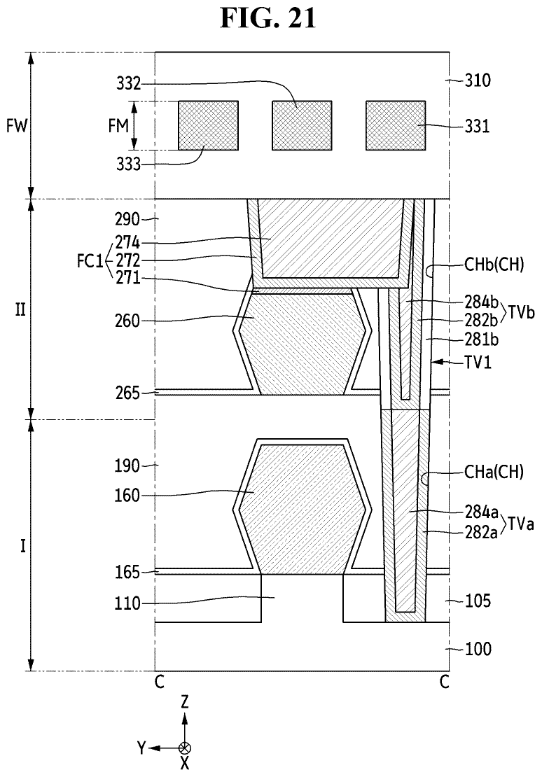

Referring to FIG. 21, a frontside wiring structure FW is formed on the second interlayer insulating film 290, the first via structure TV1, and the first frontside source/drain contact FC1.

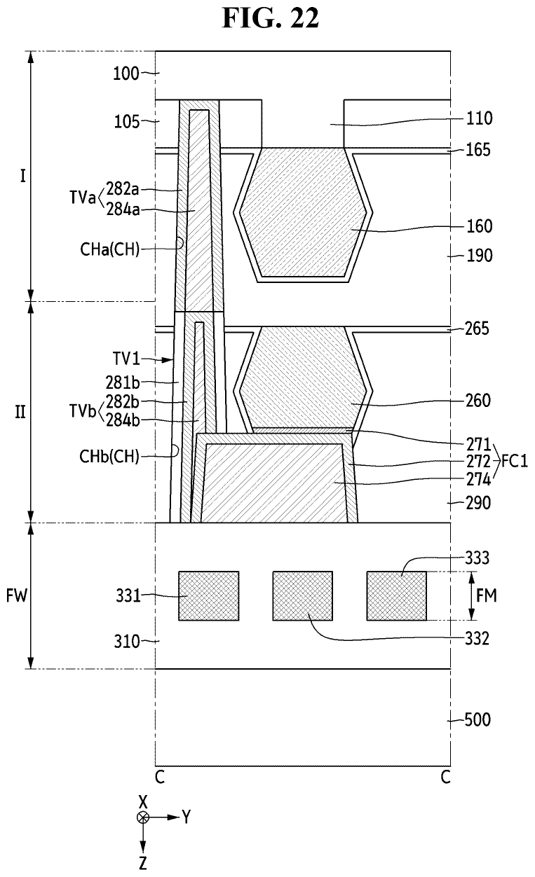

Referring to FIG. 22, a carrier substrate 500 is attached to the frontside wiring structure FW.

For example, the carrier substrate 500 may be attached to the resulting structure illustrated in FIG. 21. After the carrier substrate 500 is attached, the resulting structure illustrated in FIG. 21 may be flipped.

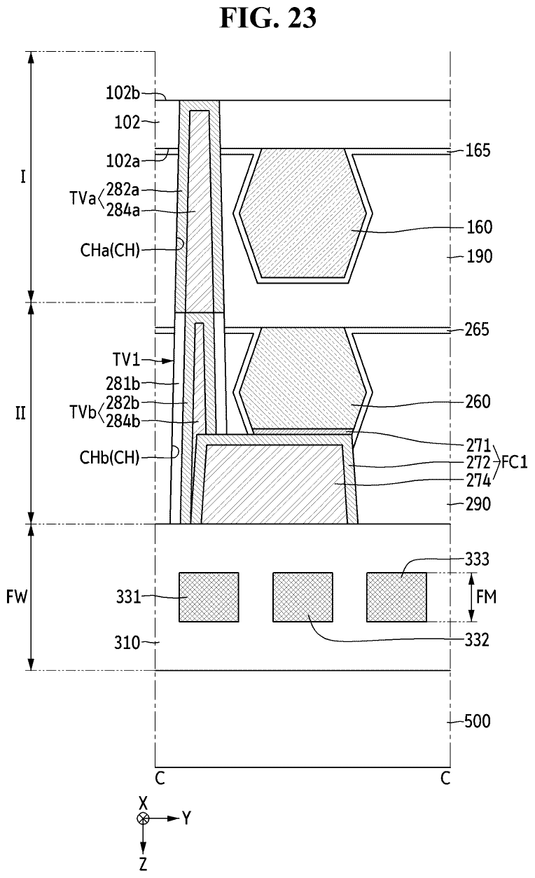

Referring to FIG. 23, a substrate 102 is formed.

For example, the base substrate 100 and the fin pattern 110 may be removed. Then, an insulating material filling the region where the base substrate 100 and the fin pattern 110 have been removed may be formed. Through this, the substrate 102, which is an insulating substrate, may be formed.

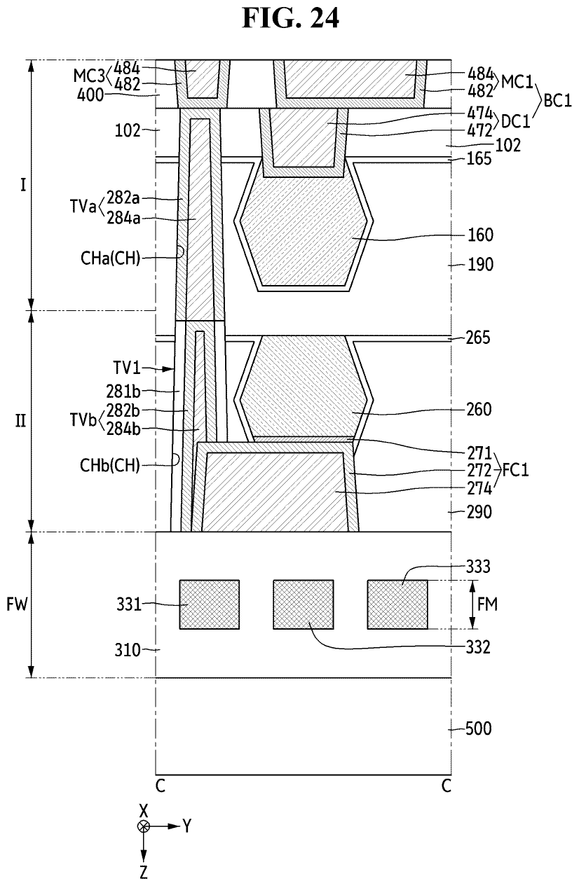

Referring to FIG. 24, a first backside source/drain contact BC1 and a third connection contact MC3 are formed.

For example, a first direct contact DC1 connected with the first source/drain pattern 160 through the substrate 102 may be formed. Thereafter, a backside insulating film 400 may be formed on a second surface 102b of the substrate 102. Thereafter, a first connection contact MC1 connected with the first direct contact DC1 may be formed within the backside insulating film 400. Additionally, a third connection contact MC3 connected with the first via structure TV1 may be formed within the backside insulating film 400.

Thereafter, referring to FIG. 5, a backside wiring structure BW is formed. Through this, the semiconductor device described above with reference to FIGS. 1 through 7A may be manufactured.

In concluding the detailed description, those skilled in the art will appreciate that many variations and modifications may be made to the disclosed and contemplated embodiments without substantially departing from the principles of the present disclosure. Therefore, the disclosed embodiments of the disclosure are used in a generic and descriptive sense only and not for purposes of limitation.

What is claimed is:

1. A semiconductor device, comprising:
a first region and a second region sequentially arranged in a first direction;
a first active pattern extending in a second direction intersecting the first direction in the first region;
a second active pattern extending in the second direction in the second region;
a gate structure extending in a third direction intersecting the first and second directions on the first and second active patterns;
a via structure extending in the first direction across the first and second regions, on and spaced apart from a side surface of the gate structure in the third direction, wherein the via structure includes a first via pattern and a second via pattern sequentially stacked in the first direction, and a first liner insulating film extending along a side surface of the second via pattern, on an upper surface of the first via pattern; and
a boundary provided between the first and second via patterns.

2. The semiconductor device of claim 1, wherein a width of the via structure in the second direction increases toward the first direction.

3. The semiconductor device of claim 1, wherein the first via pattern includes a seam spaced apart from a lower surface of the first via pattern in the first direction and contacting a lower surface of the second via pattern.

4. The semiconductor device of claim 1, wherein the second via pattern includes a seam spaced apart from the upper surface of the first via pattern in the first direction.

5. The semiconductor device of claim 1, wherein, at the boundary between the first and second via patterns, a first width of the first via pattern in the second direction is greater than a second width of the second via pattern in the second direction.

6. The semiconductor device of claim 5, wherein a thickness of the first liner insulating film in the third direction is greater than or equal to a difference between the first and second widths.

7. The semiconductor device of claim 1, wherein the via structure includes a third via pattern stacked on the second via pattern, and a third liner insulating film extending along a side surface of the third via pattern, on an upper surface of the second via pattern.

8. The semiconductor device of claim 7, wherein a first thickness of the first liner insulating film and a third thickness of the third liner insulating film are different from each other.

9. The semiconductor device of claim 8, wherein the third thickness is greater than the first thickness.

10. The semiconductor device of claim 1, further comprising:
a first source/drain pattern connected with the first active pattern, on the side surface of the gate structure;
a second source/drain pattern connected with the second active pattern, on the side surface of the gate structure; and
wherein the via structure is spaced apart from the first and second source/drain patterns in the third direction.

11. A semiconductor device, comprising:
a first active pattern and a second active pattern spaced apart from each other in a first direction and extending in a second direction intersecting the first direction;
a gate structure extending in a third direction intersecting the first and second directions, and penetrated by each of the first and second active patterns;
a first source/drain pattern connected with the first active pattern, on a side surface of the gate structure;
a second source/drain pattern connected with the second active pattern, on the side surface of the gate structure;
an interlayer insulating film on the first and second source/drain patterns, on the side surface of the gate structure;
a via hole extending in the first direction within the interlayer insulating film and spaced apart from the first and second source/drain patterns in the third direction, wherein the via hole includes a first sub-hole and a second sub-hole, with the second sub-hole above the first sub-hole in the first direction, wherein a width of the second sub-hole is greater than or equal to a width of the first sub-hole in the third direction; and
a via structure in at least a portion of the via hole, wherein the via structure includes a first via pattern in at least a portion of the first sub-hole, a first liner insulating film extending along a side surface of the second sub-hole, and a second via pattern connected with the first via pattern, on the first liner insulating film, wherein, at a boundary between the first and second via patterns, a width of the first via pattern is greater than a width of the second via pattern in the second direction.

12. The semiconductor device of claim 11, wherein:
the first via pattern includes a first seam spaced apart from a lower surface of the first via pattern in the first direction and contacting a lower surface of the second via pattern; and
the second via pattern includes a second seam spaced apart from an upper surface of the first via pattern in the first direction.

13. The semiconductor device of claim 11, wherein:
the first via pattern includes a first barrier conductive film and a first filling conductive film sequentially stacked within the first sub-hole; and
the second via pattern includes a second barrier conductive film and a second filling conductive film sequentially stacked on the first liner insulating film.

14. The semiconductor device of claim 11, wherein the first liner insulating film includes a silicon nitride film.

15. The semiconductor device of claim 11, wherein:
the via hole includes a third sub-hole above the second sub-hole in the first direction;
a width of the third sub-hole is greater than or equal to a width of the second sub-hole in the third direction; and
the via structure includes a second liner insulating film extending along a side surface of the third sub-hole, and a third via pattern connected with the second via pattern, on the second liner insulating film.

16. A semiconductor device, comprising:
a substrate including a first surface and a second surface opposite to each other in a first direction;
a first active pattern extending in a second direction intersecting the first direction on the first surface;
a second active pattern spaced farther from the first surface than the first active pattern in the first direction, and extending in the second direction;
a gate structure extending in a third direction intersecting the first and second directions, and penetrated by each of the first and second active patterns;
a first source/drain pattern connected with the first active pattern, on a side surface of the gate structure;
a second source/drain pattern connected with the second active pattern, on the side surface of the gate structure;
backside wiring patterns on the second surface; and
a via structure extending in the first direction to electrically connect the second source/drain pattern and the backside wiring patterns, wherein the via structure includes a first via pattern and a second via pattern sequentially stacked on the backside wiring patterns, and a liner insulating film extending along a side surface of the second via pattern, on an upper surface of the first via pattern, and a boundary provided between the first and second via patterns.

17. The semiconductor device of claim 16, further comprising:
a frontside source/drain contact extending in the third direction on an upper surface of the second source/drain pattern and connecting the second source/drain pattern and the via structure.

18. The semiconductor device of claim 16, wherein:
the backside wiring patterns include a first backside wiring pattern and a second backside wiring pattern to which different power supply voltages are applied;
the via structure is electrically connected with the first backside wiring pattern; and
the first source/drain pattern is electrically connected with the second backside wiring pattern.

19. The semiconductor device of claim 18, further comprising:
a backside source/drain contact extending in the third direction on a lower surface of the first source/drain pattern and connecting the first source/drain pattern and the second backside wiring pattern.

20. The semiconductor device of claim 18, wherein the first and second backside wiring patterns each extend in the second direction.
